(19) United States
(12) Patent Application Publication
(10) Pub. No.: US 2023/0108281 A1
(43) Pub. Date: Apr. 6, 2023

(54) LIGHT-EMITTING DEVICE AND METHOD OF MANUFACTURING THE SAME

(71) Applicant: NICHIA CORPORATION, Anan-shi (JP)

(72) Inventor: Masanobu SATO, Tokushima-shi (JP)

(73) Assignee: NICHIA CORPORATION, Anan-shi (JP)

(21) Appl. No.: 17/944,854

(22) Filed: Sep. 14, 2022

(30) Foreign Application Priority Data
Sep. 21, 2021 (JP) 2021-153133

(51) Int. Cl. H01L 33/60

(52) U.S. Cl. CPC H01L 33/60; H01L 2933/0058

(57) ABSTRACT

A light-emitting device includes: a substrate having a first surface; one or more light-emitting elements disposed on the first surface of the substrate; and a first reflective member disposed on the first surface of the substrate and surrounding the light-emitting elements, the first reflective member including: a first resin, and a plurality of first hollow particles in the first resin. The first reflective member has an uneven surface formed with the first hollow particles. A surface roughness Ra of the first reflective member is 0.10 µm or more and 3.0 µm or less, and a reflectance of the first reflective member is 40% or more.

### CROSS-REFERENCE TO RELATED APPLICATIONS

This application claims priority to Japanese Patent Application No. 2021-153133, filed on Sep. 21, 2021, the entire contents of which are incorporated herein by reference.

### BACKGROUND

The present disclosure relates to a light-emitting device and a method of manufacturing the light-emitting device.

Various light-emitting devices using light-emitting elements have been developed. For example, Japanese Patent No. 5648422 B2 discloses a light-emitting device including a light-emitting element surrounded by a frame formed of a light reflective resin and filled inside with a light reflective resin having a low viscosity. For another example, Japanese Patent No. 5953736 B2 discloses a light-emitting device including a sealing member that seals a light-emitting element and has an uneven surface caused by particles of a filler.

### SUMMARY

The present disclosure is intended to provide a light-emitting device that includes a light-emitting element surrounded by a reflective member having a high reflectance, and inhibits having stray light, and a method of manufacturing the light-emitting device.

A light-emitting device according to an embodiment of the present disclosure includes a substrate having a first surface, one or more light-emitting elements disposed on the first surface of the substrate, and a first reflective member that surrounds the light-emitting elements and is disposed on the first surface of the substrate. The first reflective member includes a first resin and two or more first hollow particles included in the first resin. The first reflective member has: an uneven surface formed with the first hollow particles; a surface roughness Ra of 0.10 µm or more and 3.0 µm or less; and a reflectance of 40% or more.

A method of manufacturing a light emitting device according to the embodiment of the present disclosure includes: a step of preparing an intermediate assembly that includes a substrate having a first surface and one or more light-emitting elements disposed on the first surface of the substrate, and a mixture of a first resin and two or more first hollow particles; a step of applying the mixture on the first surface of the substrate so as to surround the light-emitting element; and a step of forming a first reflective member by curing the mixture. After the step of forming the first reflective member, the first reflective member has: an uneven surface formed with the first hollow particles; a surface roughness Ra of 0.10 µm or more and 3.0 µm or less; and a reflectance of 40% or more.

According to the embodiment of the present disclosure, the light-emitting device, which includes the light-emitting element surrounded by the reflective member having the high reflectance, and inhibits having stray light, and the method of manufacturing the light-emitting device are obtained.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view of a light-emitting device according to an embodiment.

FIG. 2 is a schematic plan view of the light-emitting device according to the embodiment.

FIG. 3 is a cross-sectional view of a scene in FIG. 2, taken along a line III-III.

FIG. 4 is a cross-sectional view of the scene in FIG. 2, taken along a line IV-IV.

FIG. 5 is a cross-sectional view of the scene in FIG. 2, taken along a line V-V.

FIG. 6 is a cross-sectional view of the scene in FIG. 2, taken along a line VI-VI.

FIG. 7 is a schematic plan view of a first reflective member, a second reflective member, and wires of the light-emitting device according to the embodiment.

FIG. 8 is an expanded schematic cross-sectional view of a part of the first reflective member of the light-emitting device according to the embodiment.

FIG. 9 is a chart showing a relationship between a surface roughness Ra and a frosting level.

FIG. 10 is a schematic cross-sectional view of a substrate and the first reflective member for illustrating a method of measuring an angle between a first surface of the substrate and the first reflective member.

FIG. 11 is a flowchart of a method of manufacturing the light emitting device according to the embodiment.

FIG. 12A is a schematic plan view of a scene using the method of manufacturing the light emitting device according to the embodiment.

FIG. 12B is a schematic plan view of a scene using the method of manufacturing the light emitting device according to the embodiment.

FIG. 12C is an expanded schematic plan view of a scene using the method of manufacturing the light emitting device according to the embodiment.

FIG. 12D is a schematic plan view of a scene using the method of manufacturing the light emitting device according to the embodiment.

FIG. 12E is a schematic plan view of a scene using the method of manufacturing the light emitting device according to the embodiment.

FIG. 12F is a schematic plan view of a scene using the method of manufacturing the light emitting device according to the embodiment.

FIG. 12G is a schematic plan view of a scene using the method of manufacturing the light emitting device according to the embodiment.

FIG. 12H is a schematic plan view of a scene using the method of manufacturing the light emitting device according to the embodiment.

FIG. 13A is an expanded schematic cross-sectional view of a part of the first reflective resin according to a first modification of the embodiment.

FIG. 13B is an expanded schematic cross-sectional view of a part of the first reflective resin according to a second modification of the embodiment.

FIG. 13C is an expanded schematic cross-sectional view of a part of the first reflective resin according to a third modification of the embodiment.

FIG. 13D is an expanded schematic cross-sectional view of a part of the first reflective resin according to a fourth modification of the embodiment.

FIG. 14 is a schematic cross-sectional view of a fifth modification of the embodiment.

FIG. 15 is a partial cross-sectional view of the fifth modification of the embodiment.

FIG. 16 is an expanded schematic cross-sectional view of a part of a sealing member of the fifth modification of the embodiment.

### DETAILED DESCRIPTION

### Embodiments

Hereinafter, a light-emitting device and a manufacturing method of the light-emitting device according to the embodiment are described with reference to the drawings. Note that sizes and positional relationships in the drawings may be exaggerated for the purpose of illustration. Further, dimensions and positional relationships of members may be not coincident between a plan view and a corresponding cress-sectional view. To avoid the drawings from becoming excessively complicated, a part of elements may not be shown, or an end view, showing only a cut surface, may be used as a cross-sectional view. Further, in a description below, an up-down direction, a right-left direction, and a front-rear direction are relative, and not absolute. Identical names and symbols basically indicate identical or homogeneous members, and detailed descriptions thereof may be omitted. Further, in the embodiments, “cover” or “covering” includes not only a case in which one directly contacts the other, but also a case in which one indirectly contacts the other, such as via another member. In the present description, a plan view means a view from a light-extracting surface of the light-emitting device.

### Light-Emitting Device

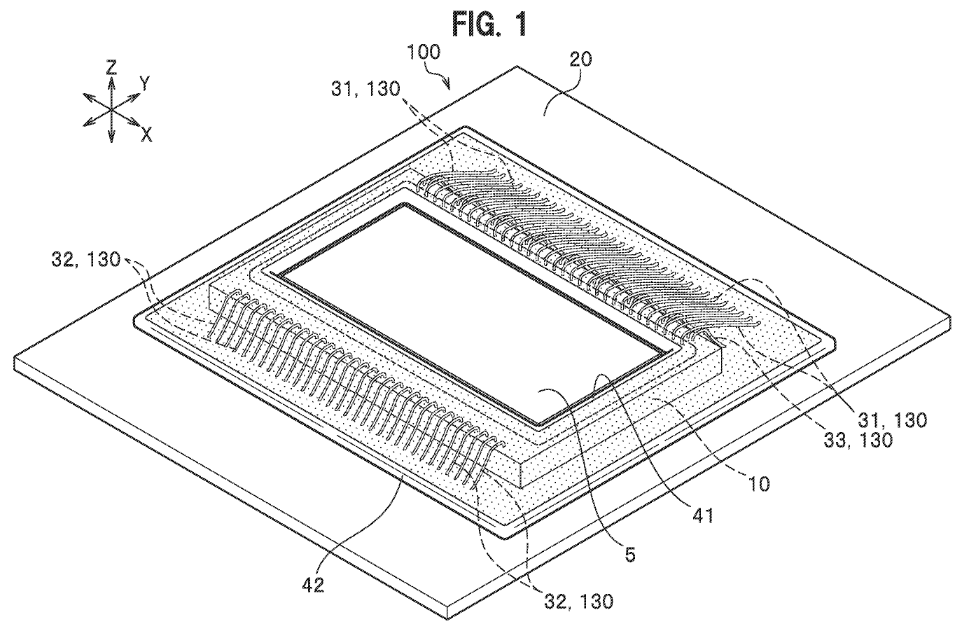

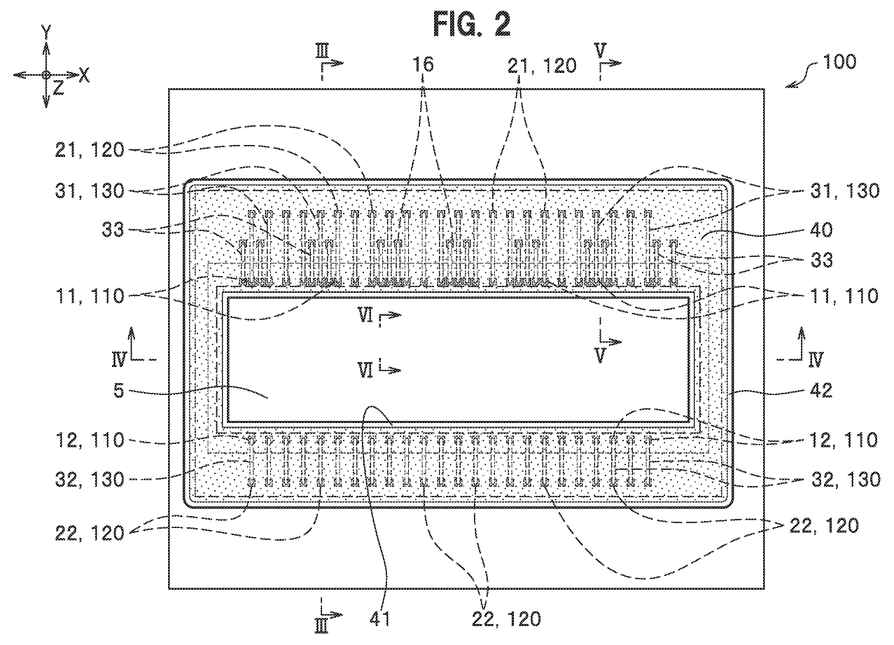

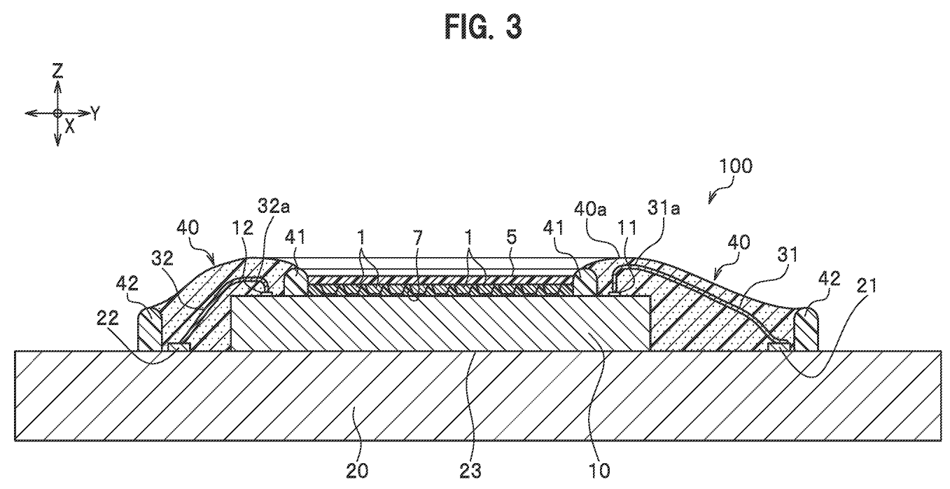

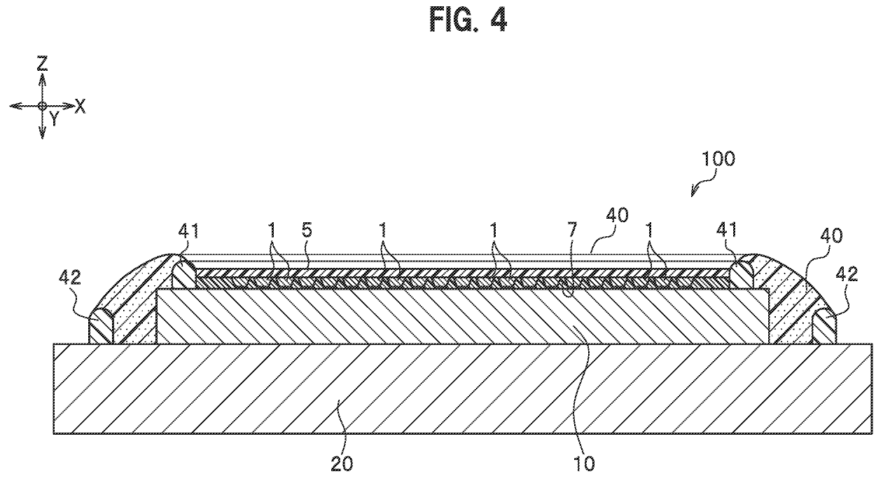

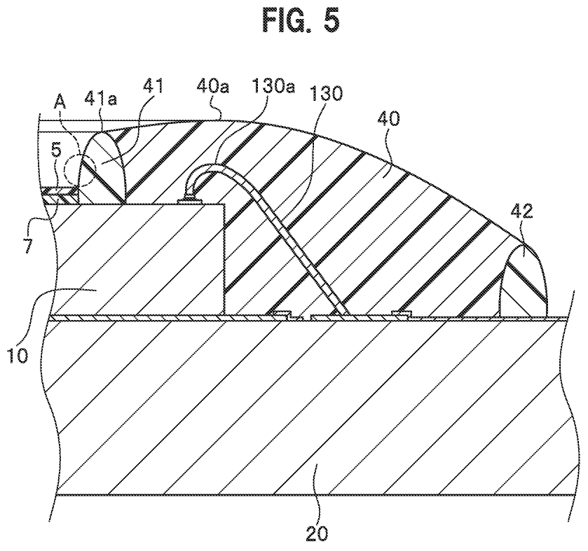

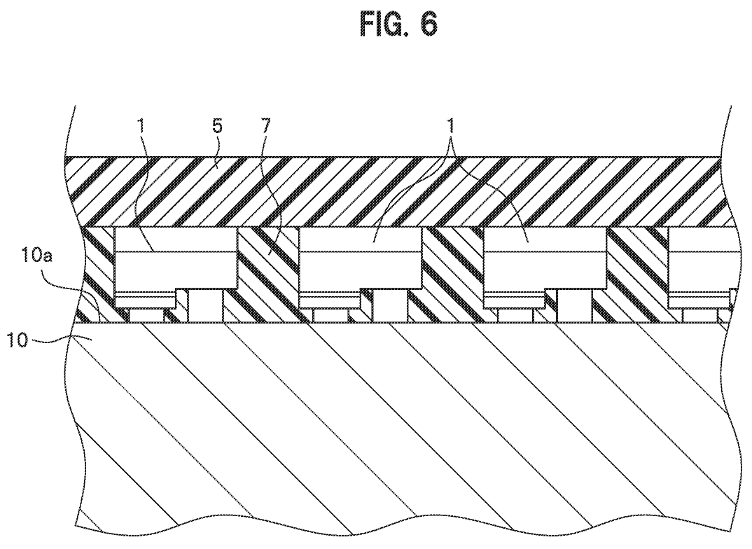

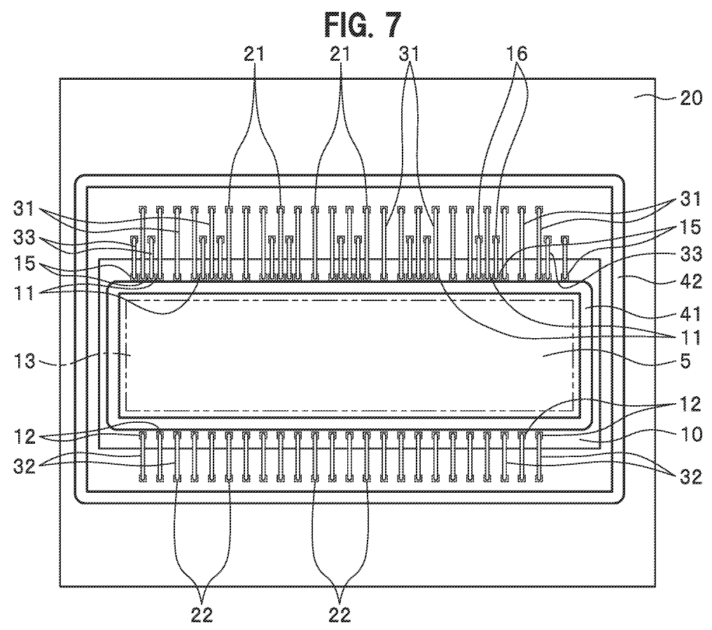

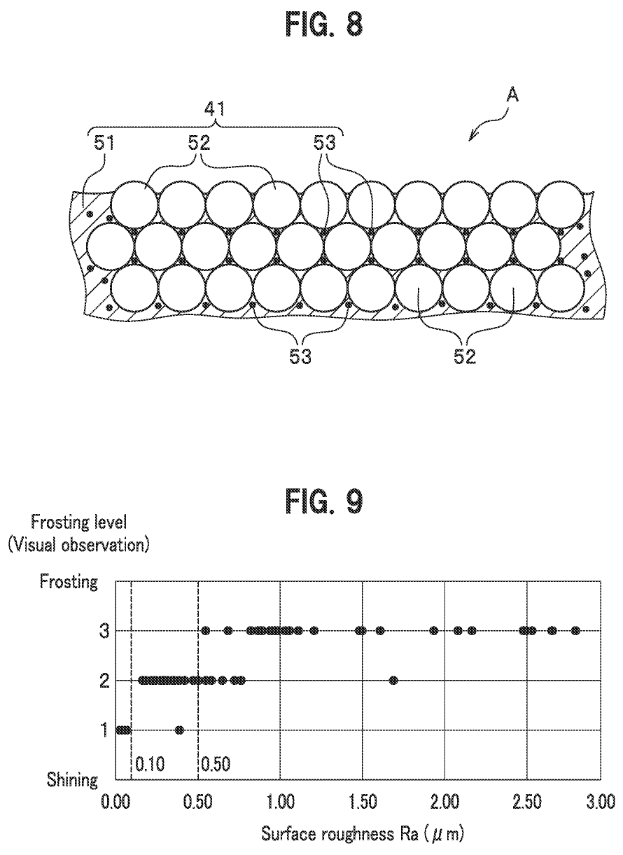

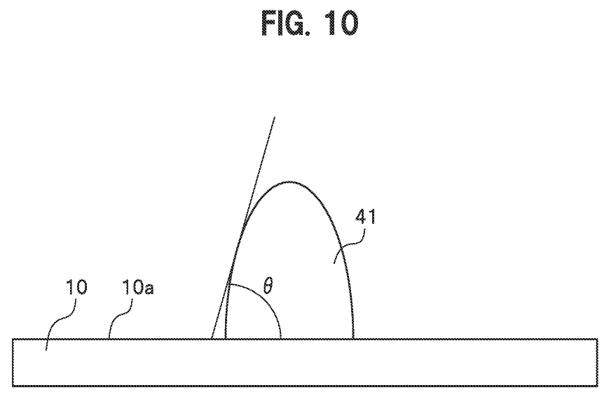

FIG. 1 is a schematic perspective view of the light-emitting device according to the embodiment. FIG. 2 is a schematic plan view of the light-emitting device according to the embodiment. FIG. 3 is a cross-sectional view of a scene in FIG. 2, taken along a line III-III. FIG. 4 is a cross-sectional view of the scene in FIG. 2, taken along a line IV-IV. FIG. 5 is a cross-sectional view of the scene in FIG. 2, taken along a line V-V. FIG. 6 is a cross-sectional view of the scene in FIG. 2, taken along a line VI-VI. FIG. 7 is a schematic plan view of a first reflective member, a second reflective member, and wires of the light-emitting device according to the embodiment. FIG. 8 is an expanded schematic cross-sectional view of a part of the first reflective member of the light-emitting device according to the embodiment. Note that FIG. 8 shows a part of a region A of FIG. 5. FIG. 9 is a chart showing a relationship between a surface roughness Ra and a frosting level. FIG. 10 is a schematical cross sectional view of a substrate and the first reflective member for illustrating a method of measuring an angle between a first surface of the substrate and the first reflective member. Note that, in some drawings, first wires 31, second wires 32, and/or third wires 33 arranged in a covering member 40 may be invisible, but the description is given for the purpose of illustration even in such cases as if the first wires 31 and the like were visible.

A light-emitting device 100 includes: a substrate 10 having a first surface 10a; one or more light-emitting elements 1 provided on the first surface 10a of the substrate 10; and a first reflective member 41 surrounding the light-emitting elements 1 and disposed on the first surface 10a of the substrate 10. The first reflective member 41 includes a first resin 51 and two or more first hollow particles 52 contained in the first resin 51. The first reflective member 51 has an uneven surface formed with the first hollow particles 52, a surface roughness Ra of 0.1 µm or more and 3.0 µm or less, and a reflectance of 40% or more.

The light-emitting device 100 mainly includes: two or more light-emitting devices 1; a first substrate 10 on which the two or more light-emitting elements 1 are disposed; a second substrate 20 on which the first substrate is disposed; a first wire 31 and a second wire 32, as wires 130, electrically connecting the first substrate with the second substrate; a covering member 40 covering the wires 130; a first reflective member 41 disposed on the first substrate 10 and contacting the covering member 40; a second reflective member 42 disposed on the second substrate 20 and contacting the covering member 40; a third reflective member 7 disposed on the first substrate 10 and covering a side surface of the light-emitting element 1; and a light transmissive member 5 covering an upper surface of the light-emitting element 1.

Hereinafter, the components listed above are described.

### First Substrate

The first substrate 10 includes a flat supporting member and wires provided on the supporting member. The first substrate 10 has an element mounting region 13 on which the two or more light-emitting elements are disposed on the first upper surface 10a as an upper surface of the first substrate 10. The element mounting region 13 is provided with the wires to configure a predetermined electric circuit. The first substrate 10 includes two or more first terminals 110 as wiring provided on an upper surface and outside the element mounting region 13, and the first terminals 110 are electrically connected to wiring provided on the element mounting region 13. The first substrate 10 is a semiconductor substrate such as silicon, and a region of the upper surface, on which the wiring is not provided, is covered with an insulating film. The wiring can be provided inside the supporting member or on a lower surface of the supporting member. For example, the first substrate 10 can employ an integrated circuit (IC) substrate on which circuits to drive the light-emitting elements 1 are integrated.

The element mounting region 13 is provided with the two or more light-emitting elements 1 in a matrix. Meanwhile, the light-emitting elements 1 may be provided not only in a matrix having two or more rows and/or two or more columns but also in one row alone or one column alone. The element mounting region 13 in the plan view, for example, can be a rectangular region. The element mounting region 13 here is rectangular, and the first terminals 110 are provided in a row, along long sides of the rectangle, facing each other, so as to straddle the element mounting region 13.

The first terminal 110 includes: two or more first external connecting terminals 11 provided in a row, outside the element mounting region 13, along one of the long sides of the rectangular element mounting region 13; and two or more second external connecting terminals 12 provided in a row, outside the element mounting region 13, along the other of the long sides, facing said one of the long sides. The first external connecting terminal 11 is terminal that connects one end of the first wire 31. The second external connecting terminal 12 is a terminal that connects one end of the second wire 32. The first external connecting terminals 11 and the second external connecting terminals 12 here are each substantially rectangular, and are provided in a row so as to be apart from each other, along the long sides of the element mounting region 13, as an example.

The first substrate here, as an example, includes two or more first driving terminals 15 for a driving signal to turn on and off the light-emitting element 1. The first driving terminals 15, for example, are provided alternately with the first external connecting terminals 11 in the same line. The first driving terminal 15 is connected to the third wire 33 to be described below.

Further, the light-emitting elements 1 are disposed in a matrix on the first substrate 10, and electrically connected to any of the first terminals 110 (that is, the first external connecting terminals 11 and second external connecting terminals 12). The light-emitting elements 1, in groups of the predetermined number thereof, can be serially or parallelly connected to the first terminals 110.

The wires are made of, for example, a metal such as Cu, Ag, Au, Al, Pt, Ti, W, Pd, Fe, or Ni, or an alloy thereof. Such wires are formed by an electrolytic plating, non-electrolytic plating, a vapor deposition, or a sputtering.

### Second Substrate

The second substrate 20 includes a flat base member and wires provided on at least the upper surface of the base member. The second substrate 20 is provided, on an upper surface thereof, with a substrate mounting region 23 on which the first substrate 10 is mounted, and further, on the upper surface and outside the substrate mounting region 23, with a second terminal 120.

The substrate mounting region 23 is a region on which the first substrate 10 is mounted via a bonding member. The substrate mounting region 23 is set as a region having the same area as the area of the first substrate 10 in a planar view. When the first substrate 10 is rectangular in a planar view, the substrate mounting region 23 can also be rectangular. Here, the second terminal 120 includes a first wire bonding terminal 21 connected to the first external connecting terminal 11 via a wire and a second wire bonding terminal 22 connected to the first external connecting terminal 12 via a wire. The first wire bonding terminal 21 and the second wire bonding terminal 22 are provided on the second substrate 20 with the substrate mounting region 23 interposed therebetween.

The two or more first wire bonding terminals 21 are provided in a row outside the substrate mounting region 23, along one of the long sides of the rectangular substrate mounting region 23. The first wire bonding terminal 21 is connected to the other end of the first wire 31 that has one end thereof connected to the first external connecting terminal 11.

The second wire bonding terminals 22 are provided in a row outside the substrate mounting region 23, along the other of the long sides of the rectangular substrate mounting region 23 (in other words, a side positioned on the opposite side of the substrate mounting region 23 to said one of the long sides). The second wire bonding terminal 22 is connected to the other end of the second wire 32 that has one end connected to the second external connecting terminal 12. The first wire bonding terminals 21 and the second wire bonding terminals 22 here are each substantially rectangular, and are provided in a row so as to be apart from each other, along the long sides of the substrate mounting region 23, as an example.

The second terminal 120, for example, is formed with the same material and forming method as those of the wiring of the first substrate 10 as described above.

The second substrate 20 here, as an example, is provided, on the upper surface thereof, with two or more second driving terminals 16 used for driving with the driving signal to turn on and off the light-emitting element 1. The second driving terminal 16, for example, is provided on the upper surface at a position inner than the first wire bonding terminal 21 (or closer to the substrate mounting region 23). The second driving terminal 16 is connected to the third wire 33 to be described below.

The base member is preferably made of a material having a high heat dissipation property, and is more preferably made of a material having a high light blocking property or high strength in addition to a high heat dissipation property. Specifically, the material includes a ceramic such as an aluminum, an aluminum nitride, or a mullite, a resin such as a phenol resin, an epoxy resin, a polyamide resin, a bismaleimide triazine resin, or a polyphthalamide, and further a composite composed of a resin and a metal or a ceramic. The base member can have a plate shape, or employ one having one or more cavities in an upper surface thereof. In this case, the second substrate 20 can have the first substrate 10 mounted in the cavity, using a bottom of the cavity as the substrate mounting region.

The second substrate 20 may be provided with wiring for mounting the first substrate 10 on the upper surface of the substrate mounting region 23. The first substrate 10 and the second substrate 20 can be bonded to each other via a bonding member such as an Ag sintered body, a solder, or an adhesive resin.

### Wire

The wires 130 may be conductive wires employing a metal such as gold, copper, platinum, and aluminum and/or an alloy containing at least one of the metals listed above. Particularly, it is preferable to use gold, which has an excellent thermal resistance. A diameter of the wire 130 is 15 µm or more and 50 µm or less, for example. Note that the wire 130 includes a first wire 31 and the second wire 32, which are connected to the first terminal 110 and the second terminal 120, and the third wire 33 for a driving signal to turn on and off the light-emitting element 1. The third wire 33 is connected to a first driving terminal 15 disposed on the first substrate 10, and the second driving terminal 16 disposed on the second substrate 20. The first wire 31, the second wire 32, and the third wire 33 are formed of comparable members, but having different lengths.

The wires 130 can be provided across the long side of the first substrate 10, which is substantially rectangle in a planar view, so as to be substantially orthogonal to the long side, for example.

### Light-Emitting Element

The light-emitting element 1 is substantially rectangular in a planar view, for example, and includes a semiconductor laminate and positive and negative electrodes provided on the surface of the semiconductor laminate. The light-emitting element 1 includes the positive and negative electrodes on the same surface thereof, and is flip-chip-mounted on the first substrate 10 with the surface having the electrodes as a lower surface. In this case, an upper surface, which is opposite to the surface having the electrodes, is set as a main light extracting surface of the light-emitting element 1. Note that, in the light-emitting device 100, the light-emitting elements 1 are mounted on the first substrate 10 at a predetermined interval in the row and column directions. Sizes and/or the number of the light-emitting elements 1 to be used is/are appropriately chosen depending on a shape of the desired light-emitting element 1. Most of all, it is preferable to mount smaller light-emitting elements 1 in greater number, so as to be densely mounted. This allows an illumination range to be controlled with the larger number of divisions, and the light-emitting element 1 is used as a light source of a high-resolution lighting system. For example, the device may use the one thousand to 20 thousand light-emitting devices 1 in a rectangular shape in a planar view, having side lengths in a range of 40 µm to 100 µm, so that the light-emitting elements 1 are arranged in a matrix to form a rectangle as a whole.

The light-emitting element 1 can be selected from those emitting light of any wavelengths. For example, a light-emitting element 1 configured to emit blue or green light can be selected from those using ZnSe, a nitride semiconductor (In_{X}Al_{Y}Ga_{1-X-Y}N, where 0≤X, 0≤Y, X+Y≤1), or GaP. In addition, a light-emitting element 1 configured to emit red light can employ a semiconductor such as GaAlAs or AllnGaP. Further, any semiconductor light-emitting elements made of one or more materials other than the above identified materials can be employed. A structure or emission color of the light-emitting element 1 can be appropriately selected according to a purpose.

### Bonding Member

The light-emitting element 1, as shown in FIG. 6, is bonded on a wiring provided in the element mounting region 13 of the first substrate 10, with the conductive bonding member. When the light-emitting element 1 is flip-chip-mounted on the first substrate 10, a bump made of a metallic material such as Au, Ag, Cu, and Al can be employed as a bonding member. Alternatively, a lead-free solder such as AuSn-based alloy or Sn-based solder can be employed as a bonding member. In this case, the light-emitting element 1 is bonded to the first substrate 10 by a reflow method. Still alternatively, a conductive adhesive containing a conductive particle in a resin can be employed as a bonding member. A plating method may be used for bonding the light-emitting element 1 with the first substrate 10, such as using a cupper as a plating material.

Still alternatively, bonding the light-emitting element 1 with the first substrate 10 may be executed with the electrodes of the light-emitting element 1 directly bonded to the wires on the first substrate 10 without a bonding member.

### Third Reflective Member

The third reflective member 7, as shown in FIG. 6, is a covering member that covers the upper surface of the first substrate 10 and the side surface of the light-emitting element 1. The light-emitting element 1 has the upper surface exposed from the third reflective member 7. The third reflective member 7 may cover a space between the lower surface of the light-emitting element 1 and the first substrate 10. The third reflective member 7 reflects light emitted from the side surface of the light-emitting element 1 to cause the light to exit from the upper surface of the light transmissive member 5 that is an emitting surface of the light-emitting device 100. This improves a light extraction efficiency of the light-emitting device 100. Further, when the light-emitting elements 1 are turned on individually, a border between a light-emitting area and a non-light emitting area is distinguished. This improves a contrast ratio between the light-emitting area and the non-light emitting area. Further, the third reflective member 7 can be disposed apart from the first reflective member 41, or in contact with the first reflective member 41.

The third reflective member 7 preferably employs a soft resin having a relatively low elasticity and an excellent shape-following property. The third reflective member 7 can employ a resin having an excellent insulation property such as a thermosetting resin such as an epoxy resin or a silicon resin. The third reflective member 7 can employ a white resin in which a resin as a base body contains particles of a light reflective material. The light reflective material can be suitably selected from a titanium oxide, an aluminum oxide, a zinc oxide, a barium carbonate, a barium sulfate, a boron nitride, an aluminum nitride, and a glass filler. Note that the third reflective member 7 may contain a light absorbing material such as a carbon black or a graphite.

### Light Transmissive Member

The light transmissive member 5 has a light transmittance and covers the upper surface of the light-emitting elements 1. The light transmissive member 5 collectively covers the upper surface of the light-emitting elements 1 and the upper surface of the third reflective member 7. An upper surface of the light transmissive member 5 functions as a light-emitting surface of the light-emitting device 100. The light transmissive member 5 may include a wavelength conversion member. Here, as an example, the light transmissive member 5 contains the wavelength conversion member to cause wavelengths of at least a part of the light from the light-emitting elements 1 to be converted and emitted outside. An example of the wavelength conversion member is a phosphor.

The light transmissive member 5 is substantially rectangular in a planar view, and disposed to cover the upper surfaces of the light-emitting elements 1.

The light transmissive member 5 processed in a sheet form or a plate form can be disposed on the light-emitting elements 1, or the light transmissive member 5 can be applied on the light-emitting elements 1 in a layered form by splaying. Alternatively, the light transmissive member 5 can be formed by an injection forming using such as dies, a transfer molding, or a compression molding.

An example of the light transmissive member 5 containing the wavelength conversion member is a phosphor sintered body, or a base material such as a resin, a glass, or another mineral, which contains phosphor powder. The base material can employ an epoxy resin, a silicon resin, a resin mixture thereof, or a transmissive material such as glass. The light transmissive member 5 has a thickness of about 20 µm or more and 100 µm or less, for example. The light transmissive member 5 is formed in a size to cover the whole upper surfaces of the light-emitting elements 1. Further, the light transmissive member 5 here extends to a position where it contacts the first reflective member 41 to be described below.

An example of the phosphor is a nitride-based phosphor such as an yttrium-aluminum-garnet-based phosphor (such as Y₃ (Al, Ga) ₅O₁₂: Ce), a lutetium-aluminum-garnet-based phosphor (such as Lu₃ (Al, Ga) ₅O₁₂: Ce), a terbium-aluminum-garnet-based phosphor (such as Tb₃ (Al, Ga) ₅O₁₂: Ce), a β-sialon-based phosphor (such as (Si, Al)₃ (O, N)₄: Eu), an α-sialon-based phosphor (such as Ca (Si, Al)₁₂ (O, N)₁₆: Eu), a CASN-based phosphor (such as CaAlSiNs: Eu), and an SCASN-based phosphor (such as (Sr, Ca) AlSiN₃: Eu), a fluoride-based phosphor such as a KSF-based phosphor (such as K₂SiFe: Mn), a KSAF-based phosphor (such as K₂ (Si, Al) F₆: Mn), and an MGF-based phosphor (such as 3.5MgO·0.5MgF₂·GeO₂: Mn), a perovskite structure phosphor (such as CsPb (F, Cl, Br, l)₃), or a quantum dot phosphor (such as CdSe, InP, AglnS₂, orAglnSe₂).

### Covering Member

The covering member 40 is a light-blocking resin that covers the wires 130 (specifically, the first wires 31 and the second wires 32) at positions outside of the element mounting region 13. The covering member 40 is provided in a frame shape in a planar view, as an example, to cover the first wires 31 and the second wires 32, and to surround the element mounting region 13. The covering member 40 is provided to contact the first reflective member 41 to be described below. The covering member 40 also covers the third wire 33. Further, the covering member 40 is provided apart from the light transmissive member 5.

The frame-shaped covering member 40 has a portion thereof along a long side of the first substrate 10 in a substantially rectangular shape in a planar view having a wider width than that along a short side of the first substrate 10. Further, the covering member 40 is provided such that the height of the covering member 40 (in other words, a distance from the upper surface of the second substrate 20 to the upper surface of the covering member 40) is set to be the highest at a point right above a vertex 130a (here, a loop-top of the wire) of the wire 130. In other words, the covering member 40 is provided such that a vertex 40a thereof overlaps the vertex 130a of the wire 130. Note that a position of the vertex 40a of the covering member 40 is arranged to be upper than that of the vertex 41a of the first reflective member 41, to be described below

The covering member 40 having a light blocking property, for example, employs a resin that contains a filler having a light blocking property. An example of a base resin is a silicon resin, a modified silicon resin, an epoxy resin, a modified epoxy resin, an acrylic resin, or the like. The filler having a light blocking property includes a light absorbing material such as a pigment, a carbon black, or a graphite, or the same light reflective material as the light reflective material contained in the third reflective member described above. Specifically, the filler includes a white resin having an excellent light reflective property, a black resin having an excellent light absorbing property, or a gray resin having a light reflective property and a light absorbing property. Further, the covering member 40 can be layered with the above resins.

Among the above resins, in consideration of deterioration of the resin caused by light absorption, the covering member 40 preferably employs a white resin having a light reflective property at least on the uppermost surface.

### First Reflective Resin and Second Reflective Resin

The light-emitting device 100 includes, on the first substrate 10 between the element mounting region 13 and the first terminal 110, the first reflective member 41 that is provided along the element mounting region 13, and contacts the covering member 40. Further, the light-emitting device 100 includes, on the upper surface of the second substrate 20, the second reflective member 42 that is provided outside the second terminal 120 and contacts the covering member 40. That is, the covering member 40 is provided between the first reflective member 41 and the second reflective member 42 from the upper surface of the first substrate 10 to the upper surface of the second substrate 20.

The covering member 40 is provided between the first reflective member 41 provided on the first substrate 10 to surround the element mounting region 13, and the second reflective member 42 provided on the second substrate 20 to surround the substrate mounting region 23. Such an arrangement of the covering member 40 is formed by providing an uncured resin to become the covering member 40 inside the frame surrounded by the first reflective member 41 and the second reflective member 42. In other words, the first reflective member 41 and the second reflective member 42 are used as a dam blocking a flow of the uncured resin when the covering member 40 is supplied.

The first reflective member 41 and the second reflective member 42 have predetermined heights with uncured resin provided in layers in a height direction thereof. For example, the first reflective member 41 and the second reflective member 42 are formed by ejecting the resin adjusted to have a predetermined viscosity from a nozzle as a layer on the second substrate 20, and repeating the work to obtain the predetermined heights.

The height of the first reflective member 41 from the upper surface of the first substrate 10 can be the same as, or different from, that of the second reflective member 42 from the second substrate 20. When the heights are different, the height of the second reflective member 42 is preferably higher than that of the first reflective member 41. In this case, a difference, between the height from the upper surface of the second substrate 20 to the vertex of the first reflective member 41 and the height from the upper surface of the second substrate 20 to the vertex of the second reflective member 42, can be smaller than the thickness of the first substrate 10 (or a distance from the upper surface to the lower surface of the first substrate 10). This inhibits the uncured covering member 40 from overflowing outside the second reflective member 42, when the covering member 40 is provided between the first reflective member 41 and the second reflective member 42.

The first reflective member 41 is provided in a rectangular frame shape that surrounds the element mounting region 13 in a planar view. The covering member 40, as an example, is provided to contact the vertex of the first reflective member 41. The first reflective member 41 is provided in a rectangular frame shape in a planar view on the first substrate 10 along the outer periphery of the element mounting region 13. The first reflective member 41 is provided between the long side of the element mounting region 13 and the first terminals 110 at positions along the long side of the element mounting region 13. The first reflective member 41 is provided on the first substrate 10 between the element mounting region 13 and the outer periphery of the first substrate 10 at positions along the short side of the element mounting region 13.

The first reflective member 41 preferably has an inclined surface that inclines toward the vertex thereof from the first substrate 10. The inclined surface is preferably a curved surface which is convex outward. Specifically, the first reflective member 41 preferably has a substantially semi-circular shape or substantially semi-elliptical shape in a cross-sectional view in a direction perpendicular to the first surface 10a of the first substrate 10. This makes the surface of the covering member 40 contacting the first reflective member 41 to be a curved surface that is convex toward the covering member 40. The covering member 40 has such a shape, and thus, the light, which is emitted from the light transmissive member 5 and passes through the first reflective member 41 toward the covering member 40, is reflected toward the first substrate 10. This inhibits leaked light or stray light, which are not intended, from being directed upward (light extracting side), and thus the light-emitting device with reduced light scattering is obtained.

Note that the substantially semi-circular shape in the present embodiment is not limited to an exact semi-circle such that a true circle is divided into two, and includes a shape recognized as an approximate semi-circle. For example, the substantially semi-circular shape can be one with a circle that is distorted or deformed with tolerance or a margin of error, being divided into two. Specifically, the substantially semi-circular shape includes one with a circle, having a tolerance or an error within 5% with respect to a length of a diameter, being divided into two. When the tolerance or the error exceeds by 5% with respect to the length of the diameter, it is defined as being substantially elliptical. Note that the semi-circle does not have to be exactly divided into two.

Further, the substantially semi-elliptical shape in the present embodiment is not limited to a semi-ellipse in which an ellipse in a strict sense of a locus of points, with a sum of distances from two fixed points in a plane being constant, is divided into two equal parts, and includes a shape recognized as a substantially semi-elliptical shape. For example, the substantially semi-elliptical shape can be one with an oval, having a circle extended in one direction, an oval gold coin, or a running track being divided into two equal parts. In other words, the substantially semi-elliptical shape can be one having a substantially elliptical shape divided into two equal parts. The substantially elliptical shape also includes a shape surrounded by a pair of straight lines or curved lines extending in a longitudinal direction or transverse direction and another pair of curved lines that are connected to the above-described pair of straight lines or curved lines and curved in convex outward. For example, the substantially elliptical shape includes a shape having two sets of two adjacent ends of two parallel sides, the sides facing each other, or two curved sides, the sides facing each other, connected with two arcs having the same diameter (e.g., arcs of semi-circles), respectively. Note that the semi-ellipse does not have to be exactly divided into two equal parts.

The first reflective member 41, as shown in FIG. 8, includes the first resin 51 and the two or more first hollow particles 52 contained in the first resin 51. That is, the first reflective member 41 includes the two or more first hollow particles 52. The first reflective member 41 has an uneven surface formed with the first hollow particles 52. Specifically, the first reflective member 41 has a surface roughness Ra of 0.10 µm or more and 3.0 µm or less. When the surface roughness Ra of the first reflective member 41 is 0.10 µm or more, the light that is emitted from the light-emitting element 1 and irradiates the first reflective member 41, a reflected light in the light-emitting device or an external light are diffusely reflected, to inhibit having stray light. This allows for obtaining a desired irradiation pattern. On the other hand, when the surface roughness Ra of the first reflective member 41 is 3.0 µm or less, the uneven surface of the first reflective member 41 is easily formed.

The surface roughness Ra of the first reflective member 41 is preferably 0.50 µm or more and 2.0 µm or less. When the surface roughness Ra of the first reflective member 41 is 0.50 µm or more, having stray light is more inhibited. On the other hand, when the surface roughness Ra of the first reflective member 41 is 2.0 µm or less, the uneven surface of the first reflective member 41 is easily formed.

Note that the range of the surface roughness Ra is determined by referring to the chart in FIG. 9, indicating a relationship between the surface roughness Ra and frosting level.

The surface roughness Ra of the first reflective member 41, for example, is measured over a length of 2000 µm by a contact-type profiler (Alpha-Step-IQ, KLA Tencor) with a speed of 200 µm/s.

Note that in the light-emitting device 100, a part of the first hollow particles 52 is exposed from the first resin 51. However, as described below, the first hollow particles 52 may not be exposed from the first resin 51, with the surfaces of the first hollow particles 52 covered with the first resin 51. Further, FIG. 8 shows that the first hollow particles 52 contact each other, but the first resin 51 may intervene between the first hollow particles 52. Further, the first hollow particles 52 contacting each other can be mixed with the first resin 51 intervening between the first hollow particles 52.

The first reflective member 41 has a reflectance of 40% or more. When the first reflective member 41 has a low reflectance, that is, the first reflective member 41 has a high transmittance, the light transmitted through the first reflective member 41 is reflected by the first substrate 10 or the like, to have a risk of having stray light. Further, this also causes the inside of the first reflective member 41 to be seen through, to deteriorate the external appearance. When the reflectance of the first reflective member 41 is 40% or more, the reflectance of the first reflective member 41 is excellent, to reduce an occurrence of the above problems. The reflectance of the present disclosure is based on a light-emitting peak wavelength of the light-emitting element, but may be based on 450-nm light.

The first reflective member 41 preferably has a reflectance of 60% or more. When the reflectance of the first reflective member 41 is 60% or more, the first reflective member 41 can have a more excellent reflectance. An upper limitation of the reflectance of the first reflective member 41 is not specifically defined, but the reflectance can be 80% or less, or 90% or less. However, the reflectance of the first reflective member 41 is preferably 95% or more.

The first reflective member 41 includes the first hollow particles 52 to maintain a white color in appearance due to an effect of a refractive index difference between an outer shell of the first hollow particle 52 and an internal cavity of the first hollow particle 52. Further, this also maintains a high level of the reflectance.

The first hollow particle 52 may be a hollow glass microsphere, a hollow silica microsphere, a porous silica microsphere, a fly ash balloon, a shirasu balloon(a silas balloon), or a hollow polymer particle. In terms of heat resistance and light resistance, the first hollow particles 52 are each preferably a hollow silica microsphere or a hollow glass microsphere.

The two or more first hollow particles 52 preferably have median diameters of 16 µm or more and 65 µm or less. When the median diameter is 16 µm or more, the uneven surface of the first reflective member 41 is easily formed, to facilitate controlling the surface roughness Ra of the first reflective member 41. On the other hand, when the median diameter is 65 µm or less, the number of the first hollow particles 52 contained in the first resin 51 increases, to facilitate controlling the reflectance of the first reflective member 41. The median diameter is more preferably 20 µm or more, and further preferably 30 µm or more, in terms of facilitating controlling the surface roughness Ra of the first reflective member 41. Further, the median diameter is more preferably 60 µm or less, and further preferably 40 µm or less, in terms of facilitating controlling the reflectance of the first reflective member 41.

The median diameter is a particle diameter (cubic median diameter) at which a cubic cumulative frequency from a smaller diameter reaches 50% in a particle distribution based on volume, which is measured by a laser diffraction scattering type measurement method of particle size distribution. The laser diffraction scattering type measurement method of particle size distribution may use a laser diffraction scattering type measurement device of particle size distribution (MASTER SIZER 3000, MALVERN), for example, for measurement.

In the first reflective member 41, a content of the two or more first hollow particles 52 is preferably 20 part by mass or more and 70 part by mass or less with respect to a part by mass of the first resin 51. When the content of the first hollow particles 52 is 20 part by mass or more with respect to the part by mass of the first resin 51, the uneven surface of the first reflective member 41 is easily formed, to facilitate controlling the surface roughness Ra of the first reflective member 41. On the other hand, when the content is 70 part by mass or less, the viscosity of the first resin 51 is easily adjusted, to facilitate forming the first reflective member 41. The content of the two or more first hollow particles 52 is more preferably 20 part by mass or more and 50 part by mass or less with respect to the part by mass of the first resin 51. When the content is 50 part by mass or less, the viscosity of the first resin 51 is more easily adjusted. Further, in terms of facilitating controlling the surface roughness Ra of the first reflective member 41, the content is more preferably 30 part by mass or more.

Note that “part by mass” is an amount corresponding to a mass [g] of an additive with respect to 100 g of the base resin. That is, the part by mass of the first hollow particles 52 with respect to the part by mass of the first resin 51 is, in other words, part by mass of the first hollow particles 52 with respect to 100 part by mass of the first resin 51.

An example of the first resin 51 is a silicon resin, a modified silicon resin, an epoxy resin, a modified epoxy resin, an alkyd resin, an acrylic resin, a urethane resin, or a hybrid resin containing at least one of said resins.

The first resin 51 preferably employs a resin having a higher viscosity than that of the covering member 40. The viscosity of the first resin 51 can be adjusted by an amount of the filler to be contained in the first resin 51 for viscosity adjustment, for example.

The first resin 51 preferably has the viscosity of 200 Pa·s or more and 1200 Pa·s or less. When the viscosity of the first resin 51 is 200 Pa·s or more, a desired shape of the first reflective member 41 is easily formed. On the other hand, when the viscosity is 1200 Pa·s, a resin from an injecting device is rapidly injected, to improve working efficiency. The first resin 51 more preferably has the viscosity of 220 Pa·s or more, and further preferably 250 Pa·s or more, in terms of facilitating forming a desired shape of the first reflective member 41. Further, the first resin 51 more preferably has the viscosity of 900 Pa·s or less, and further preferably 550 Pa·s or less, in terms of facilitating injecting the resin.

The first resin 51 can be added with a nano filler such as AEROSIL (registered trademark) to increase the viscosity and add thixotropy. In the present embodiment, the first resin 51 includes a nano filler 53. An example of the nano filler 53 is a nano silica. Further, when the nano filler 53 is filled a lot and the viscosity has become too high, adding a solvent lowers the viscosity. The solvent available is preferably compatible with the base resin. When a silicon resin is used for the base, an example of the solvent is an aromatic-series-based carbon hydride (a xylene, a toluene), a petroleum-based carbon hydride (a benzine, a petroleum ether), or an ether kind (a diethyl ether, tetrahydrofuran).

The first reflective member 41 has the two or more first hollow particles 52 dispersed in the first resin 51. The first hollow particles 52 being dispersed in the first resin 51 improves the reflectance of the first reflective member 41. In the present embodiment, the first hollow particles 52 being dispersed in the first resin 51 means that when predetermined parts in the cross section of the first reflective member 41 are observed, a difference in proportions of the first hollow particles 52 is less than 1.5 times anywhere in any two parts having the same areas. Calculation of the proportion (existence rate) of the first hollow particles 52 is specifically performed as below.

First, a cross-sectional image of the first reflective member 41 is taken to calculate the existence rate of the first hollow particles 52 at any two parts. The images of the two parts are taken at the same magnification, and the existence rate of the first hollow particles 52 is calculated by “the area of the first hollow particles 52 divided by the area of the resin part” in the cross-sectional image. Each area can be calculated from the cross-sectional image taken by an electronic microscope (JSM-IT200, JEOL) with a measuring function of the microscope, or calculated by a mass of a cut-out printed paper. Note that the area of the resin part excludes areas of non-resin portions in the image, such as the substrate.

The light-emitting device 100 preferably has an angle of 60 degrees or more and 135 degrees or less between the first surface 10a of the first substrate 10 and the first reflective member 41. As long as the angle is within the above range, the first reflective member 41 is easily formed and the function of the first reflective member 41 is more improved.

To calculate the angle between the first surface 10a of the first substrate 10 and the first reflective member 41, the image of the cross-section of the first reflective member 41 is taken by a microscope (VHX-700F, KEYENCE) to measure the angle θ between the first surface 10a of the first substrate 10 and the outer periphery of the first reflective member 41 by a measuring function of the microscope, as shown FIG. 10.

In the light-emitting device 100, the second reflective member 42 is disposed lower than the light-emitting element 1 and the light transmissive member 5 (that is, disposed on an opposite side of the light extracting side). Thus, the second reflective member 42 may have, or may not have, translucency to the light emitted from the light-emitting element 1. The second reflective member 42 is used in a manufacturing process as a dam to block the uncured covering member 40, as with the first reflective member 41. Thus, the second reflective member 42 is preferably provided in the same or continuous step as the first reflective member 41, and the same resin as the first resin 51 of the first reflective member 41 is preferably used in terms of simplifying the manufacturing method.

The second reflective member 42 may have the surface roughness Ra of 0.10 µm or more and 3.0 µm or less, and may have the reflectance of 40% or more, as with the first reflective member 41. The other setup may be the same as that of the first reflective member 41.

The light-emitting device 100 including the above configuration can be used as a light source of a vehicle head lights, as an example. In this case, a light from the light source is irradiated to the outside through a lens, for example. The light-emitting device 100 has the light-emitting element 1 turned on by an external power switch. The light-emitting device 100 is configured to individually drive a predetermined part of or whole of the light-emitting elements 1.

A light-emitting device may be developed into a vehicle head light with variable light distribution, for example, specifically, one having two or more LEDs aligned or one having an LED (a multi-chip type) with two or more light-emitting elements that can be individually turned on. The light from these LEDs is emitted forward through a lens of a lighting fixture, but directionality of the light is more important for a precise light distribution control.

As a manufacturing method of a light-emitting device, a method is well known in which a frame is formed with a light reflective resin around a light-emitting element and an inside of the frame is filled with a light reflective resin with low viscosity. However, a head light or a lighting fixture manufactured with this method may have light, which is diffusely reflected therein, reflected by a light reflective resin, to have stray light. Then, the stray light comes out through a lens, to cause an unintended irradiation pattern.

As a preventive measure of stray light, it is conceivable that a resin part is blackened to absorb excess light, but this lowers an output power of the LED. Further, when the sun light enters the lighting fixture, the resin part absorbs the sun light, to have a risk of the blackened resin part being burned out. Further, in a case in which a filler absorbing shortwave light, such as a titanium oxide, is added, there can be a similar concern. As for an external light reflection at a light-emitting surface or a sealing surface, such a measure is conceivable that the topmost surface is made uneven, but there have been no preventive measures for a resin frame.

In contrast to this, in the light-emitting device 100 of the present embodiment, the first hollow particles 52 is used to make the surface of the first reflective member 41 uneven. The first reflective member 41 has the surface roughness of 0.01 µm or more and 3.0 µm or less, to cause the light irradiated the first reflective member 41 to be diffusely reflected, to inhibit having stray light. This allows for obtaining the desired irradiation pattern, and when the first reflective member 41 is used in combination with a lens, an optical design of the lens is easily performed. Further, the first reflective member 41 contains the two or more first hollow particles 52, thereby having the reflectance of 40% or more. This makes the reflectance of the first reflective member 41 excellent.

### Method of Manufacturing Light-Emitting Device

Next, an example of a manufacturing method of the light-emitting device according to the embodiment is described.

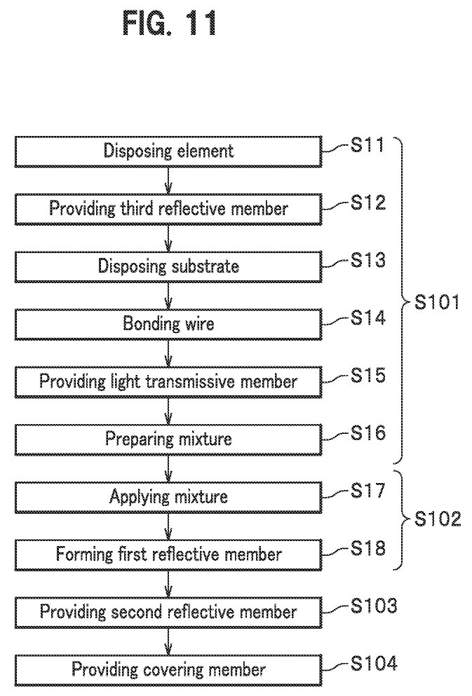

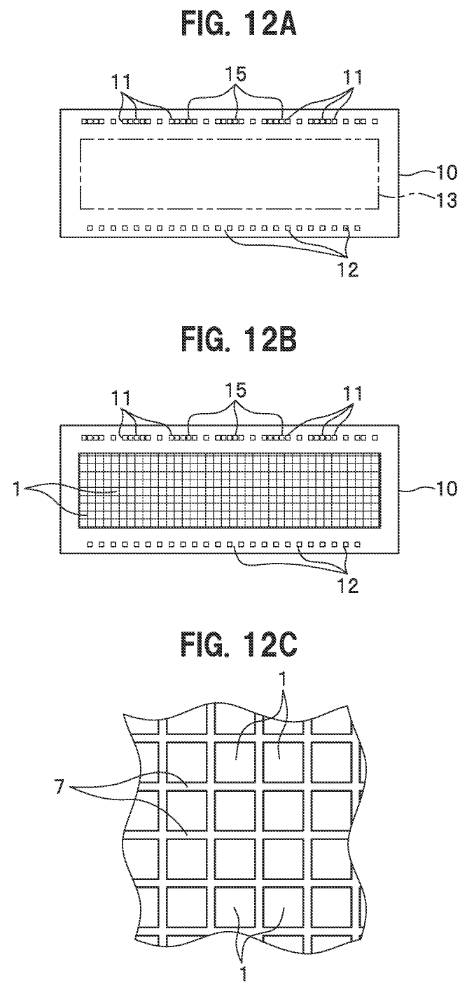

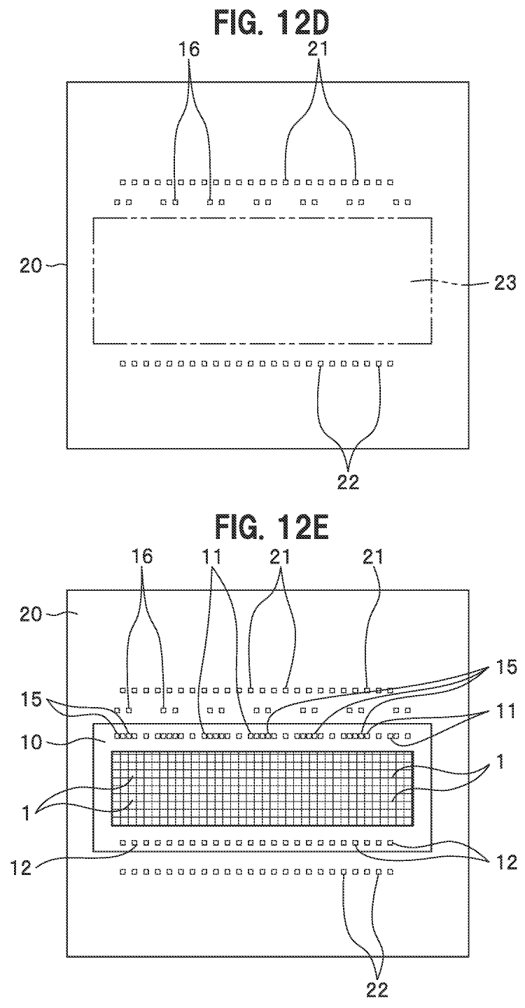

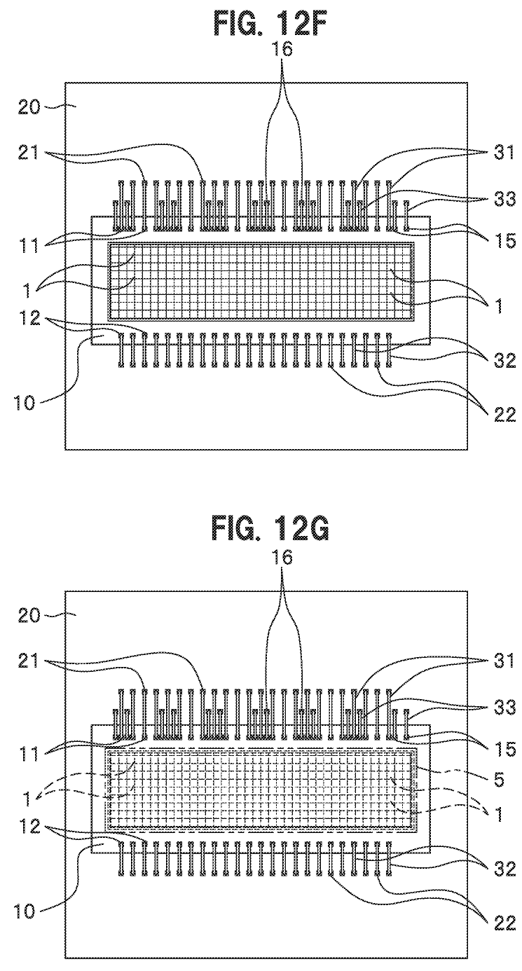

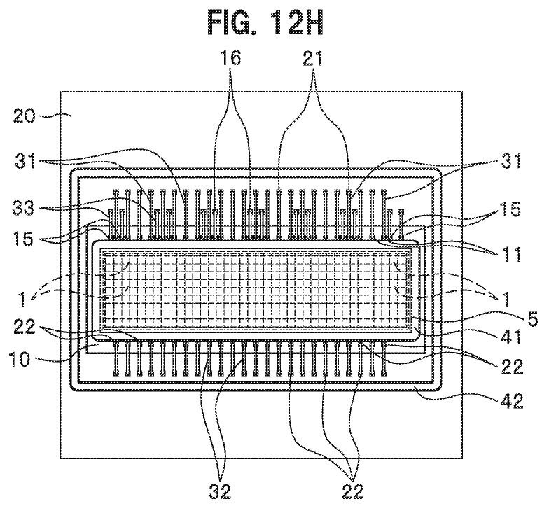

FIG. 11 is a flowchart of the method of manufacturing the light emitting device according to the embodiment. FIGS. 12A to 12H are each a schematic plan view of a scene using the method of manufacturing the light emitting device according to the embodiment. Note that FIG. 12C is the expanded schematic plan view of a scene using the method of manufacturing the light-emitting device according to the embodiment. The light-emitting element 1 is disposed at predetermined intervals, but showing the intervals are omitted except the expanded plan view in FIG. 12C.

The method of manufacturing the light emitting device includes: a step of preparing an intermediate assembly that includes the substrate 10 having the first surface 10a and the one or more light-emitting elements 1 disposed on the first surface 10a of the substrate 10, and a mixture of the first resin 51 and the two or more first hollow particles 52; a step of applying the mixture on the first surface 10a of the substrate 10 so as to surround the light-emitting element 1; and a step of forming the first reflective member 41 by curing the mixture. After the step of forming the first reflective member 41, the first reflective member 41 has the uneven surface formed by the first hollow particles 52, the surface roughness Ra of 0.10 µm or more and 3.0 µm less, and the reflectance of 40% or more.

Further, in the step of preparing the intermediate assembly, the solvent can be further mixed in the mixture, and in the step of forming the first reflective member 41, the solvent in the mixture can be vaporized to cure the mixture. In the present embodiment, a case of the solvent being mixed in the mixture is described.

Specifically, the method of manufacturing the light-emitting device includes a step S101 of preparing the intermediate assembly and the mixture, a step S102 of providing the first reflective member, a step S103 of providing the second reflective member, and a step S104 of providing the covering member.

The step S101 includes a step S11 of disposing the element, a step S12 of providing the third reflective member, a step S13 of disposing the substrate, a step S14 of bonding the wires, a step S15 of providing the light transmissive member, and a step S16 of preparing the mixture.

The step S102 includes a step S17 of applying the mixture and a step S18 of forming the first reflective member.

Hereinafter, each step is described. Note that a material and an arrangement of each member have been already described in the description of the light-emitting device 100, and a description thereof is appropriately omitted hereinbelow.

The step S11 is a step in which the two or more light-emitting elements 1 are disposed on the element mounting region 13 of the first substrate 10 (see FIGS. 12A and 12B). In the step S11, the two or more light-emitting elements 1 disposed on a supporting substrate at predetermined intervals are prepared, the light-emitting elements 1 are attached to the element mounting region 13 of the first substrate 10, and then the supporting substrate is removed. Note that before the step S11 is performed, the first substrate 10 having wirings such as the first terminal 110 provided beforehand is preferably prepared. The first terminal 110 is formed by attaching a metal foil made of such as Cu or Al, applying a paste of metal powder made of such as Cu or Ag, or plating with Cu. Further, the wiring electrically connected to the light-emitting elements 1 in the element mounting region 13 is patterned by a method such as etching or printing. Note that the first substrate 10 can be prepared by purchase.

The light-emitting elements 1 are electrically connected to the element mounting region 13 of the first substrate 10 by a method such as plating.

The step S12 is a step in which the sides of the light-emitting elements 1 are covered with the third reflective member 7 after the light-emitting elements 1 are mounted in the element mounting region 13 of the first substrate 10 (see FIGS. 12B and 12C). Here, after the light-emitting elements 1 are mounted on the first substrate 10, the third reflective member 7, such as a white resin, is provided between the light-emitting elements 1. Note that in the step S12, the upper surfaces of the light-emitting elements 1 can be covered with a mask before the third reflective member 7 is provided, and the mask is removed after the third reflective member 7 has been provided, to expose the upper surfaces of the light-emitting elements 1 from the third reflective member 7.

The step S13 is a step in which the first substrate 10 is mounted in the substrate mounting region 23 of the second substrate 20 (see FIGS. 12D and 12E). Here, the first substrate 10 on which the light-emitting elements 1 are mounted is mounted in the substrate mounting region 23 of the second substrate 20, and the first substrate 10 and the second substrate 20 are bonded together via the bonding member such as a sintered Ag or a sintered Cu. Note that before the step S13 is performed, the second substrate 20 on which the wiring such as for the second terminal 120 is provided is preferably prepared beforehand.

The step S14 is a step in which the first terminal 110 of the first substrate 10 and the second terminal 120 of the second substrate 20 are connected with each other by a wire 130 (see FIG. 12F). Specifically, the first external connecting terminals 11 of the first substrate 10 and the first wire connecting terminals 21 of the second substrate 20 are connected with each other by the first wires 31, and the second external connecting terminals 12 of the first substrate 10 and the second wire connecting terminals 22 of the second substrate 20 are connected with each other by the second wires 32. Note that the step S14 includes a step in which the first driving terminal 15 of the first substrate 10 and the second driving terminal 16 of the second substrate 20 are connected with each other by the wire 33.

The step S15 is a step in which the light transmissive member 5 covering the light-emitting elements 1 is provided (see FIG. 12G). The light transmissive member 5 is prepared in a sheet shape having a predetermined size formed beforehand, and is disposed on the light-emitting elements 1. The light transmissive member 5 can be fixed on the light-emitting elements 1 via the transmissive bonding member such as a resin, or can be fixed by utilizing tackiness of the light transmissive member 5 without any bonding member.

The step S16 is a step in which the mixture of the first resin 51 and the first hollow particles 52 is prepared. Here, the solvent and the nano filler 53 are further mixed into the mixture. Mixing the solvent facilitates mixing the members. Further, mixing the nano filler 53 facilitates adjusting the viscosity of the mixture. The amounts of the members are appropriately adjusted to obtain a desired configuration of the first reflective member 41.

The mixture is prepared by putting the members into a dedicated mixing container, mixing them with a spatula by hand, and then mixing them with a mixer, for example.

In the step of preparing the intermediate assembly, a content of the solvent in the mixture is preferably 1 part by mass or more and 30 part by mass or less with respect to a part by mass of the first resin 51. When the content is one part by mass or more with respect to the part by mass of the first resin 51, each member is easily mixed. On the other hand, when the content is 30 part by mass or less, the solvent is easily vaporized while the mixture is cured, to facilitate making the surface of the first reflective member 41 uneven.

Note that the step S16 can be performed before the step S15. That is, the mixture can be prepared beforehand, and mixed again just before the mixture is applied in the step S17.

The step S102 is a step in which the first reflective member 41 is provided on the upper surface of the first substrate 10, between the element mounting region 13 and the first terminal 110, so as to be arranged along the element mounting region 13 (see FIG. 12H). The step S102 includes the steps S17 and S18.

The step S17 is a step in which the mixture is applied on the first surface 10a of the first substrate 10 so as to surround the light-emitting elements 1.

In the step S17, a nozzle of a dispenser is moved along the element mounting region 13, while the uncured mixture forming the first reflective member 41 is supplied from the nozzle, to apply the mixture forming the first reflective member 41. When the mixture is applied, applying the mixture is preferably started within 30 minutes after the mixture has been mixed by hand (for one minute or more at 1000 rpm or more, for example), to disperse the first hollow particles 52 in the first resin 51.

The step S18 is a step in which the first reflective member 41 is formed by curing the mixture. The curing the mixture is performed under a condition of a temperature of 140° C. or more and 160° C. or less, and a duration of two hours or more and six hours or less. In the step S18, the solvent is vaporized to reduce the amount of the mixture, while the mixture is cured, to have the first hollow particles 52 provided on the surface of the first reflective member 41 to make the surface of the first reflective member 41 uneven.

After the step of forming the first reflective member 41, the first reflective member 41 has the uneven surface formed with the first hollow particles 52, and has the surface roughness Ra of 0.10 µm or more and 3.0 µm or less. After the step of forming the first reflective member 41, the first reflective member 41 preferably has the surface roughness Ra of 0.50 µm or more and 2.0 µm or less. Further, after the step of forming the first reflective member 41, the first reflective member 41 has the reflectance of 40% or more. After the step of forming the first reflective member 41, the first reflective member 41 preferably has the reflectance of 60% or more. Further, after the step of forming the first reflective member 41, the angle between the first surface 10a of the first substrate 10 and the first reflective member 41 is preferably 60 degrees or more and 135 degrees or less. These items have been already described in the description of the light-emitting device 100.

The step S103 is a step in which the second reflective member 42 is provided on the upper surface of the second substrate 20 at outer positions than the second terminals 120 on the second substrate 20 (see FIG. 12H). Note that the second reflective member 42 preferably employs the same material as the first reflective member 41. This allows for executing the step S103 as the same step as the step S102.

In the steps S102 and S103, the second reflective member 42 can be first provided through the step S103, and then first reflective member 41 can be provided through the step S102. Further, the steps S102 and S103 can be performed at the same time, to dispose the first reflective member 41 and the second reflective member 42 substantially at the same time.

The step S104 is a step in which the light-blocking covering member 40 is disposed at an outer position than the first reflective member 41, to border the first reflective member 41 and cover the wire 130. Specifically, the step S104 is a step in which the light-blocking covering member 40, which has the base material of a resin having a lower viscosity than the first reflective member 41 and the second reflective member 42, is provided between the first reflective member 41 and the second reflective member 42. The covering member 40 is provided over the first substrate 10 and the second substrate 20. This causes the covering member 40 to also cover the side surface of the first substrate 10.

Hereinabove, the embodiment to carry out the disclosure has been more specifically described. However, the subject matters of the present disclosure are not limited thereto and should be broadly construed based on appended claims. Further, the subject matter of the disclosure includes various modifications and variations thereof based on the description.

Hereinafter, modifications are described. Note that materials and arrangements of the members have been already described in the description of the embodiment, and descriptions thereof are appropriately omitted below.

### Modifications

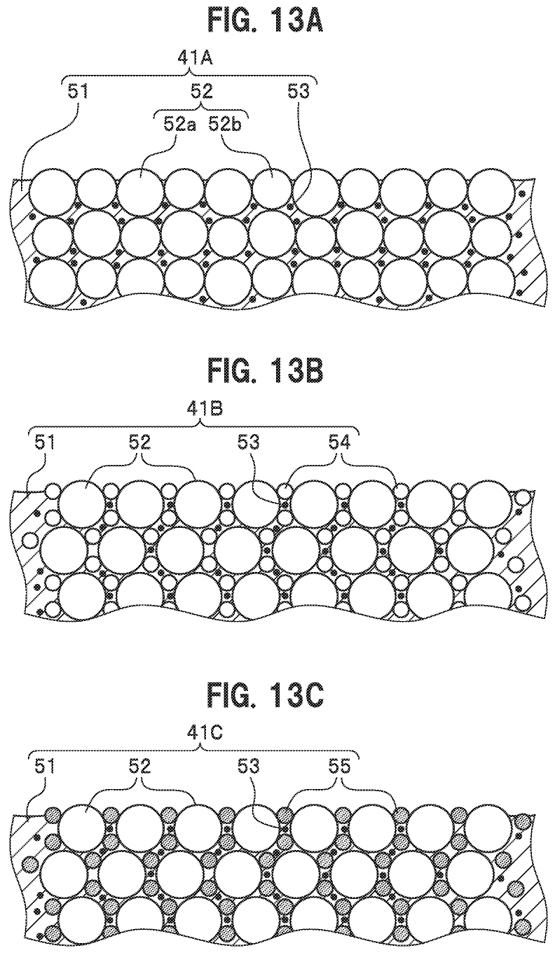

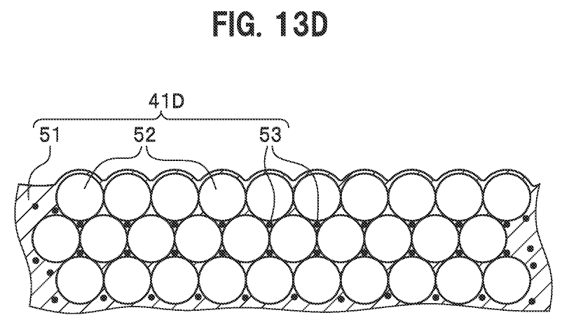

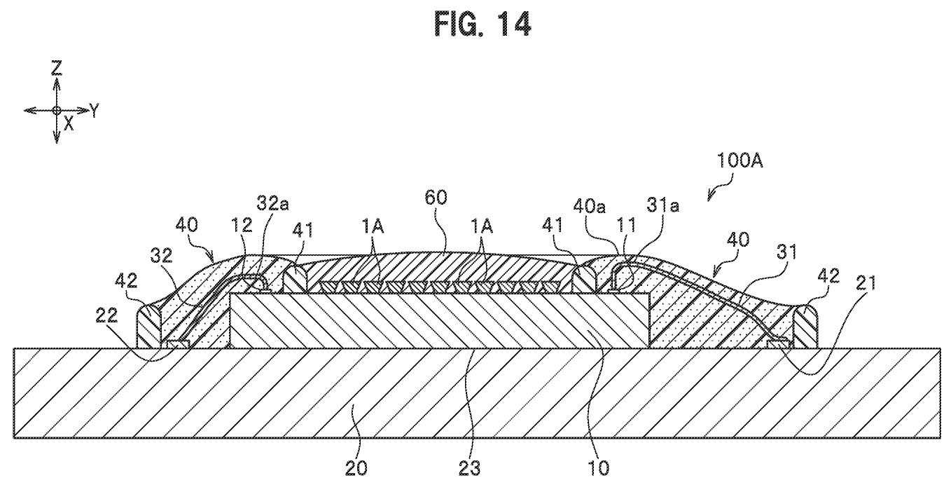

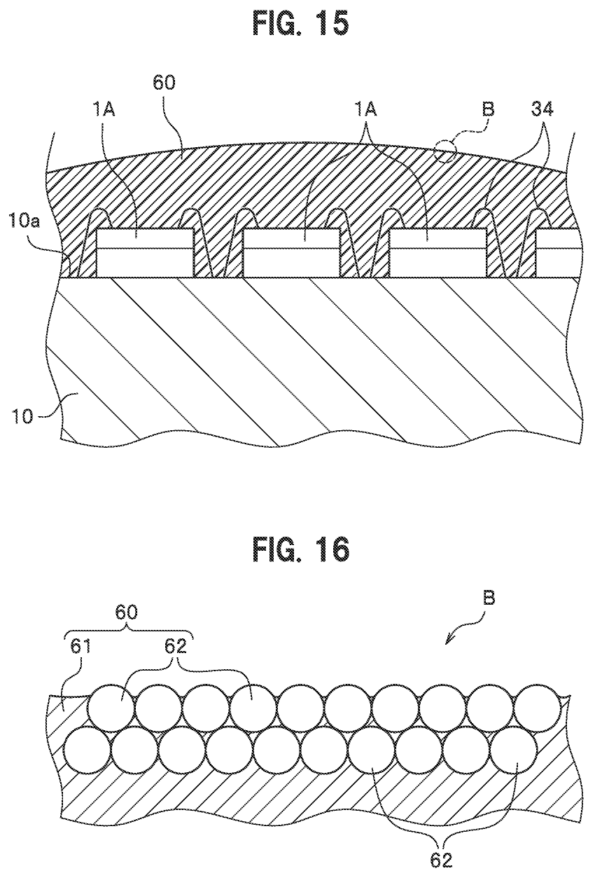

FIGS. 13A to 13D are each an expanded schematic cross-sectional view of a part of the first reflective member 41 of a first modification to a fourth modification of the embodiment, respectively. FIG. 14 is a schematic cross-sectional view of a fifth modification of the embodiment. FIG. 15 is a partial cross-sectional view of the fifth modification of the embodiment. FIG. 16 is a schematic expanded cross-sectional view of a part of the sealing member of the fifth modification of the embodiment. Note that FIG. 16 schematically shows a portion indicated by a symbol B in FIG. 15. Further, components already described above are denoted by the same symbol with no description thereof, or are omitted to avoid duplicate description thereof.

The two or more first hollow particles 52 can employ a combination of the first hollow particles 52 each having a different particle diameter from one another. Further, the first hollow particles 52 can be used in combination with one or more particles of an oxide particle including Ti, Zn, Zr, Al, or Si, a non-hollow spherical particle, and a particle having a different refractive index from the first resin 51 of the base material, such as AlN or MgF. Amounts of light reflection and light transmission vary depending on a contained concentration or a density of the particles, and therefore an additive amount and the density are adjusted according to a shape or a size of the light-emitting device. Further, a first reflective member can contain the other particles as a filler or the like. A mixture proportion of the particles to be contained in the first reflective member is adjusted to have a desired surface roughness Ra and reflectance.

Specifically, the first reflective member can have a configuration illustrated in each of FIGS. 13A to 13C.

### First Modification

As shown in FIG. 13A, a first reflective member 41A includes first hollow particles 52a each having a large median diameter and first hollow particles 52b each having a small median diameter. Even with such a configuration, the reflectance of the first reflective member 41A can be high, and experiencing stray light is inhibited.

### Second and Third Modifications

As shown in FIG. 13B, a first reflective member 41B includes oxide particle 54.

As shown in FIG. 13C, a first reflective member 41C includes non-hollow spherical particles 55. The spherical particle 55 is made of silica or glass, for example.

The oxide particles 54 and the spherical particles 55 have smaller median diameters than the first hollow particles 52, and thus enter gaps between the first hollow particles 52. These configurations improve the reflectance. Note that the oxide particles 54 and the spherical particles 55 are partly exposed from the first resin 51. However, the oxide particles 54 and the spherical particles 55 may not exposed from the first resin 51, so that the surfaces of the oxide particles 54 and spherical particles 55 are covered with the first resin 51.

### Fourth Modification

As shown in FIG. 13D, a first reflective member 41D includes the first hollow particles 52 not exposed from the first resin 51, and the surfaces of the first hollow particles 52 are covered with the first resin 51. Such a configuration makes the reflectance of the first reflective member 41D high and inhibits experiencing stray light, even if the first hollow particles 52 is not exposed from the first resin 51 in connection with an amount of solvent mixed with the mixture, an amount of solvent to be vaporized or the like, when the light-emitting device is manufactured, for instance.

### Fifth Modification

A light-emitting device 100A includes a light-emitting element 1A disposed on the substrate 10 by face-up mounting. The light-emitting element 1A has positive and negative electrodes, which are provided on a surface of a semiconductor laminate, electrically connected to the first substrate 10 via element wires 34. The light-emitting device 100A further includes a sealing member 60 covering the light-emitting element 1A, on the first surface 10a of the first substrate 10. The sealing member 60 includes a second resin 61 and two or more second hollow particles 62 contained in the second resin 61. The sealing member 60 covers the light-emitting element 1A and the element wires 34 in a planar view. The sealing member 60 protects the light-emitting element 1A and the like from external force, dust, moisture, and the like.

The sealing member 60 includes the two or more second hollow particles 62 in the second resin 61. The second hollow particles 62 are preferably distributed unevenly at positions closer to a front surface of the sealing member 60. The second hollow particles 62 being distributed unevenly at positions closer to the front surface of the sealing member 60 allows for forming an uneven front surface of the sealing member 60, to inhibit the sealing member 60 from shining due to external light. The sealing member 60 preferably has the surface roughness Ra of 0.01 µm or more and 3.0 µm or less. When the sealing member 60 has the surface roughness Ra of 0.10 µm or more, the shining of the sealing member 60 is further inhibited. On the other hand, when the sealing member 60 has the surface roughness Ra of 3.0 µm or less, the uneven front surface of the sealing member 60 is easily formed.

The second hollow particles 62 being unevenly distributed on the front surface of the sealing member 60 shall mean that the sealing member 60, when one or more predetermined portions thereof in a vertical cross section with respect to the first surface 10a of the first substrate 10 is observed, a proportion of the second hollow particles 62 at positions closer to the front surface thereof is greater than that at positions closer to the bottom surface thereof by 1.5 times or more. The proportion (existence rate) of the second hollow particles 62 is specifically calculated as follows.

A cross-sectional image of the sealing member 60 is first taken to calculate the existence rate of the second hollow particles 62 in each of an image at a position closer to the front surface including the front surface and an image at a position closer to the bottom surface including the bottom surface. The images at positions closer to the front and bottom surfaces are taken at the same magnification, and the existence rate of the second hollow particles 62 is calculated by “the area of the second hollow particles 62 divided by the area of the resin part” in the cross-sectional images. Each area can be calculated from the cross-sectional images taken by an electronic microscope (JSM-IT200, JEOL) with a measuring function of the microscope, or calculated by a mass of a cut-out printed paper. Note that the area of the resin part excludes areas of non-resin portions in the image, such as the substrate.

In the light-emitting device 100A, a part of the second hollow particles 62 is exposed from the second resin 61. However, the surface of the second hollow particles 62 can be covered with the second resin 61 with the second hollow particles 62 not exposed from the second resin 61. Further, FIG. 16 shows that the second hollow particles 62 contact each other, but the second resin 61 can intervene between the second hollow particles 62. Further, the second hollow particles 62 contacting each other and the second hollow particles 62 with the second resin 61 intervening therebetween can be mixed. The second hollow particles 62 can employ the same particles as the first hollow particles 52.

The two or more second hollow particles 62 preferably each have a median diameter of 16 µm or more and 65 µm or less. The median diameter is more preferably 20 µm or more, and further preferably 30 µm or more. Further, the median diameter is preferably 60 µm or less, and further preferably 40 µm or less. Further, the second hollow particle 62 is preferably the hollow silica microsphere or the hollow glass microsphere. The reasons for these are the same as in the case of the first hollow particles 52. The second resin 61 can employ the same resin as the first resin 51.

The sealing member 60 can contain the nano filler 53. Further, the two or more second hollow particles 62 can employ a combination of second hollow particles 62 having different particle diameters. Further, the second hollow particles 62 can be used in combination with one or more particles of the oxide particle 54, the non-hollow spherical particle 55, and a particle having a different refractive index from the second resin 61 of the base material, as with the first reflective member. Further, the sealing member 60 can contain the other particles as a filler or the like.

Further, the sealing member 60 can include the wavelength conversion member. An example of the wavelength conversion member is a phosphor. The phosphor includes one for the light transmissive member 5 of the light-emitting device 100, for example.

In a method of manufacturing the light-emitting device 100A, the light-emitting element 1A is disposed on the first surface 10a of the first substrate 10 and the element wires 34 are connected to form the first light reflective member 41, and then the sealing member 60 is provided inside the first light reflective member 41. In a step of providing the sealing member 60, the second resin 61 mixed with the second hollow particles 62 is provided inside the first light reflective member 41 by potting or spraying, for example. After that, the second resin 61 is cured at a temperature of 120° C. or more and 200° C. or less, for example, to form the sealing member 60. Note that the viscosity of the second resin 61 is preferably adjusted to have the second hollow particles 62 unevenly distributed at positions closer to the front surface of the sealing member 60.

Other than above, the light-emitting device is assumed to include the two or more light-emitting elements, but may include a single light-emitting element alone.

Further, a light-emitting device may not include either one of the second reflective member and the sealing member. The method of manufacturing the light-emitting device can include one or more other steps during or before or after the steps to the extent that the steps are not adversely affected. For example, a step of removing a foreign object mixed into an unfinished product during manufacturing can be included.

Further, the steps can be performed in a different order to the extent possible. Further, the step of preparing mixture may not include mixing the solvent.

### PRACTICAL EXAMPLES

Hereinafter, practical examples are described. Nos. A1 to A9 are practical examples that meet the configuration of the embodiment, and Nos. B1 to B3 are comparable examples that doe not meet the configuration of the embodiment.

### No. A1

### Preparation of Resin

10 g of a base resin OE-6351 (Dimethyl silicon, DuPont Toray Specialty Materials) was put in a dedicated mixing container (Hi-resist container BHR-150, Kinki Yoki) 1 g (10 part by mass) of nano silica (RX200, NIPPON AEROSIL), 5 g (50 part by mass) of hollow glass (Glass Babbles iM16K, 3M) having a median diameter of 20 µm, and 0.5 g (5 part by mass) of toluene as a solvent were added into the mixing container, and the materials were mixed with a spatula by hand, and then the materials were evenly mixed with a mixer (AwatoriRentaro ARV-310LED, Thinky) at 1200 rpm for 3 minutes.

### Measurement of Viscosity of Resin

A viscosity of the resin with completed mixing was measured by E-type viscometer (TV-33, Touki Sangyou) at 25 degrees Celsius and at 1 rpm of revolution.

### Measurement of Transmittance and Reflectance of Cured Resin

A frame made by a fluorine resin tape of 0.18 µm stacked in two layers was attached onto a glass slide, the mixed resin was put inside the frame, the thickness of the mixed resin was adjusted to a level of the frame with a squeegee, and the mixed resin was cured at 150 degrees Celsius for four hours. The transmittance of a sample, or the cured resin, after curing was obtained by measuring a transmission spectrum, with a spectrophotometer (U-3900, Hitachi High-Tech Science) set to have light entering through the resin surface to the meter, and assuming a value at 470 nm of the obtained transmissive spectrum as a transmittance. The reflectance of the sample was obtained by measuring a reflection spectrum on the condition of including specular light, with a Spectrophotometric Colormeter (CMS-35SP, Murakami Color Research Laboratory) set to have light irradiating the meter through the resin surface. A value at 470 nm of the obtained reflection spectrum was assumed as a transmittance.

### Measurement of Surface Roughness Ra of Cured Resin

The mixed resin was put in a syringe with a needle having an inner diameter of 0.66 mm. The resin was linearly ejected by a dispenser (ML-5000XII, Musashi Engineering) on an alumina ceramic substrate, and cured at 150 degrees Celsius after four hours. A value obtained from the cured resin measured by a contact-type profiler (Alpha-Step-IQ, KLA Tencor) at a velocity of 200 µm/s over 2000 µm was assumed as a surface roughness Ra.

### Measurement of Angle Between Substrate and Cured Resin

The resin cured on the ceramic substrate was cut with a cutter knife, an image of the cross-section thereof was taken by the microscope (VHX-700F, KEYENCE), and an angle between the surface bordering the substrate and the outer periphery of the cured resin was measured with the measuring function of the microscope.

### No. A2

Into 10 g of the base resin OE-6351, 10 part by mass of nano silica (RX200) and 50 part by mass of hollow glass having a median diameter of 20 µm (Glass Babbles iM16K) were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A3

Into 10 g of the base resin OE-6351, 10 part by mass of nano silica (RX200), 50 part by mass of hollow glass having a median diameter of 40 µm (Glass Babbles S38), and 5 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A4

Into 10 g of the base resin OE-6351, 10 part by mass of nano silica (RX200), 30 part by mass of hollow glass having a median diameter of 65 µm (Glass Babbles K1), and 30 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A5

Into 10 g of the base resin OE-6351, 10 part by mass of nano silica (RX200), 25 part by mass of hollow glass having a median diameter of 16 µm (Glass Babbles iM30K), 25 part by mass of hollow glass having a median diameter of 40 µm (Glass Babbles S38), and 3 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A6

Into 10 g of the base resin OE-6351, 10 part by mass of nano silica (RX200), 40 part by mass of hollow glass having a median diameter of 40 µm (Glass Babbles S38), 10 part by mass of non-hollow spherical silica having a median diameter of 0.5 µm (ADMAFINE SO-C2, Admatechs), and 5 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A7

Into 10 g of the base resin OE-6351, 10 part by mass of nano silica (RX200), 40 part by mass of the hollow glass having a median diameter of 40 µm (Glass Babbles S38), 10 part by mass of titanium oxide having a median diameter of 0.5 µm (R-960, Chemours Company), and 5 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A8

Into 10 g of the base resin OE-6351, 10 part by mass of nano silica (RX200), 25 part by mass of the hollow glass having a median diameter of 16 µm (Glass Babbles iM30K), 25 part by mass of the hollow glass having a median diameter of 40 µm (Glass Babbles S38), 10 part by mass of alumina having a median diameter of 0.8 µm (SUMICORUNDUM AA-03, SUMITOMO CHEMICAL), and 3 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. A9

Into 10 g of the base resin OE-6351, 10 part by mass of nano silica (RX200), 20 part by mass of hollow glass having a median diameter of 65 µm (Glass Babbles K1), and 5 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No B1

Into 10 g of the base resin OE-6351, 10 part by mass of nano silica (RX200), 100 part by mass of titanium oxide having a median diameter of 0.5 µm (R-960, Chemours), and 10 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. B2

Into 10 g of the base resin OE-6351, 10 part by mass of nano silica (RX200), 400 part by mass of non-hollow spherical particle having a median diameter of 20 µm (KYKLOS FR-2400TS, TATSUMORI), and 10 part by mass of toluene as a solvent were added and well mixed, and then the mixed resin was applied on the ceramic substrate and cured. The same methods as with No. A1 were used for the preparation of the resin, the curing, the measurement of viscosity of the resin, and the measurement of the cured resin.

### No. B3

Into 10 g of the base resin OE-6351, 10 part by mass of the hollow glass having a median diameter of 40 µm (Glass Babbles S38) was added and well mixed, and then the mixed resin was applied on the ceramic substrate and cured. The same methods as with No. A1 were used for the preparation of the resin, the curing, the measurement of viscosity of the resin, and the measurement of the cured resin.

The results are shown in TABLE 1. Note that, in TABLE 1, items not measured are indicated by “-.”

TABLE 1

| No. | Viscosity (Pa·s) | Transmittance (%) | Reflectance (%) | Surface Roughness Ra (µm) | Angle between Substrate and Cured Resin (° ) |
|---|---|---|---|---|---|
| A1 | 339 | 21.2 | 71.3 | 0.71 | 116.8 |
| A2 | 607 | 23.0 | 70.0 | 0.39 | 101.0 |
| A3 | 427 | 31.0 | 59.1 | 1.01 | 125.3 |
| A4 | 323 | 41.5 | 48.0 | 1.36 | 120.2 |
| A5 | 319 | 32.3 | 58.1 | 0.63 | 114.5 |
| A6 | 393 | 40.2 | 49.6 | 1.62 | 126.8 |
| A7 | 523 | 7.2 | 88.2 | 1.03 | 137.0 |
| A8 | 411 | 21.2 | 71.7 | 0.52 | 110.5 |
| A9 | 374 | 47.1 | 41.1 | 0.58 | 117.0 |
| B1 | 580 | 0.3 | 95.6 | 0.06 | 126.0 |
| B2 | 350 | 79.1 | 10.0 | 0.90 | 120.0 |
| B3 | 6.9 | - | - | - | 8.5 |

As shown in TABLE 1, Nos. A1 to A9 met the configuration of the embodiment, and the reflectance and surface roughness of the cured resin were favorable. A detailed results were as follows.

No. A1 was added with a solvent and had a larger surface roughness Ra than No. A2 having no solvent added.

Nos. A3 and A4 used the hollow glass having larger median diameters than that of No. A1, and had a larger surface roughness Ra than that of No. A1. However, the reflectance was slightly decreased.

No. A4 used the hollow glass having a larger median diameter than that of No. A3, and had a larger surface roughness Ra than that of No. A3. However, the reflectance was slightly decreased. Further, A4 had a larger amount of hollow glass than No. 9, and had a larger surface roughness Ra and a higher reflectance than that of No. A9.

No. A5 used the two kinds of hollow glass having different median diameters, and had a larger reflectance than that of No. A4. However, the surface roughness Ra was slightly decreased.

No. A6 used the hollow glass and the non-hollow spherical silica in combination, and had a larger surface roughness Ra than that of No. A3. However, the reflectance was slightly decreased.

No. A7 used the titanium oxide in place of the spherical silica of No. A6, both having the same median diameters, and had a higher reflectance than that of No. A6. No. A7 had the best balance between the reflectance and the surface roughness Ra.

No. A8 used the two kinds of hollow glass having different median diameters and the non-hollow alumina in combination, and had a larger reflectance than that of No. A5.

In contrast, Nos. B1 to B3 did not meet the configuration of the embodiment, and had following results.

No. B1 used the titanium oxide instead of the hollow particle, and had a high reflectance but a small surface roughness Ra.

No. B2 used the spherical silica instead of the hollow particle, and had a large surface roughness Ra but a low reflectance.

No. B3 was added with a small amount of the hollow glass, and the resin had a low viscosity, so that a cured resin with a desired shape was not formed. Thus, the angle between the cured resin and the substrate was very small.

### Industrial Availability

The light-emitting device according to the embodiments of the present disclosure may be used for various light sources, such as a vehicle headlight and a projector.

What is claimed is:

1. A light-emitting device comprising:
a substrate having a first surface;
one or more light-emitting elements disposed on the first surface of the substrate; and
a first reflective member disposed on the first surface of the substrate and surrounding the light-emitting elements, the first reflective member comprising:
a first resin, and
a plurality of first hollow particles in the first resin;
wherein the first reflective member has an uneven surface formed with the first hollow particles; and
wherein a surface roughness Ra of the first reflective member is 0.10 µm or more and 3.0 µm or less, and a reflectance of the first reflective member is 40% or more.

2. The light-emitting device according to claim 1,
wherein the surface roughness Ra of the first reflective member is 0.50 µm or more and 2.0 µm or less.

3. The light-emitting device according to claim 1,
wherein the first reflective member has a substantially semi-circular shape or substantially semi-elliptical shape in a cross-sectional view in a direction perpendicular to the first surface of the substrate.

4. The light-emitting device according to claim 1,
wherein each of the first hollow particles has a median diameter of 16 µm or more and 65 µm or less.

5. The light-emitting device according to claim 1,
wherein each of the first hollow particles includes a hollow silica microsphere or a hollow glass microsphere.

6. The light-emitting device according to claim 1,
wherein a content of the first hollow particles is 20 part by mass or more and 50 part by mass or less with respect to a part by mass of the first resin.

7. The light-emitting device according to claim 1 further comprising:
a sealing member disposed on the first surface of the substrate and covering the light-emitting element;
wherein the sealing member comprises:
a second resin, and
a plurality of second hollow particles in the second resin.

8. The light-emitting device according to claim 7,
wherein a proportion of the second hollow particles at positions closer to a front surface of the sealing member is 1.5 times or more than a proportion of the second hollow particles at positions closer to a bottom surface of the sealing member.

9. The light-emitting device according to claim 7,
wherein each of the second hollow particles has a median diameter of 16 µm or more and 65 µm or less.

10. The light-emitting device according to claim 7,
wherein each of the second hollow particles comprises a hollow silica microsphere or a hollow glass microsphere.

11. The light-emitting device according to claim 1,
wherein the first reflective member has a reflectance of 60% or more.

12. A method of manufacturing a light-emitting device comprising:
preparing an intermediate assembly comprising:
a substrate having a first surface, and
one or more light-emitting elements disposed on the first surface of the substrate;
preparing a mixture of a first resin and a plurality of first hollow particles;
applying the mixture on the first surface of the substrate so as to surround the light-emitting element; and
forming a first reflective member by curing the mixture;
wherein, after the step of forming the first reflective member, the first reflective member has an uneven surface formed with the first hollow particles; and
wherein a surface roughness Ra of the first reflective member is 0.10 µm or more and 3.0 µm or less, and a reflectance of the first reflective member is 40% or more.

13. The method of manufacturing the light-emitting device according to claim 12,
wherein the step of preparing the mixture comprises mixing the mixture with a solvent; and
wherein the step of forming the first reflective member comprises vaporizing the solvent in the mixture to cure the mixture.

14. The method of manufacturing the light-emitting device according to claim 13,
wherein, in the step of preparing the intermediate assembly, a content of the solvent in the mixture is one part by mass or more and 30 part by mass or less with respect to a part by mass of the first resin.

15. The method of manufacturing the light-emitting device according to claim 12,
Wherein, after the step of forming the first reflective member, the first reflective member has a surface roughness Ra of 0.50 µm or more and 2.0 µm or less.

16. The method of manufacturing the light-emitting device according to claim 12,
wherein, after the step of forming the first reflective member, the first reflective member has a reflectance of 60% or more.

17. The method of manufacturing the light-emitting device according to claim 12,
wherein, after the step of forming the first reflective member, an angle between the first surface of the substrate and the first reflective member is 60 degrees or more and 135 degrees or less.
